(19) United States
(12) Patent Application Publication
(10) Pub. No.: US 2010/0276670 A1
(43) Pub. Date: Nov. 4, 2010

(54) PHOTOELECTRIC DEVICE, IMAGING DEVICE, AND PHOTOSENSOR

(75) Inventors: Rui SHEN, Kanagawa (JP); Kimiatsu NOMURA, Kanagawa (JP); Hideyuki SUZUKI, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/237,751

(22) Filed: Sep. 25, 2008

(30) Foreign Application Priority Data
Sep. 28, 2007 (JP) 2007-256733

(51) Int. Cl. H01L 51/46

(52) U.S. Cl. 257/40; 257/E51.027

(57) ABSTRACT

A photoelectric device includes a photoelectric conversion layer containing an organic compound having a partial structure represented by the following formula (I) :

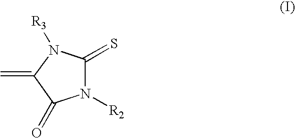

wherein R₂ and R₃ each independently represent a hydrogen atom, an alkyl group, an alkenyl group, an aryl group, or a heterocyclic group.

### CROSS-REFERENCE TO RELATED APPLICATIONS

This application claims the benefit of Japanese Patent Application JP 2007-256733, filed Sep. 28, 2007, the entire content of which is hereby incorporated by reference, the same as if set forth at length.

### FIELD OF THE INVENTION

This invention relates to a photoelectric device, an imaging device, and a photosensor.

### BACKGROUND OF THE INVENTION

Conventional visible light sensors generally have a semiconductor substrate such as a silicon substrate having formed therein a pn junction to make a photoelectric conversion portion. A widespread solid state imaging device is a flat light sensor in which photoelectric conversion units (pixels) are two-dimensionally arrayed in a semiconductor substrate, and a signal charge generated by photoelectric conversion in each pixel is transferred and read out by a CCD or CMOS system.

Color imaging is generally achieved by arranging color separation filters that transmit only light of specific wavelengths on the light incidence side of the flat light sensor. In particular, a single-panel sensor structure having two-dimensionally arrayed pixels and color filters permitting blue light, green light, or red light to pass through are regularly arranged on the respective pixels is well known for use, e.g., in digital cameras. This color imaging system has poor light utilization efficiency because the color filters permit only light of limited wavelengths, and use cannot be made of the light that is not allowed to pass. In recent years, the pixel size is getting smaller with the increasing number of pixels, and the area of the individual photodiodes is getting smaller accordingly. This has imposed the problems of aperture ratio reduction and light collection efficiency reduction.

To solve the problems, it is possible to stack photoelectric conversion portions that detect light of different wavelengths in the device thickness direction. With the light to be utilized being confined to visible light, this concept has been embodied by a color photosensing structure of U.S. Pat. No. 5,965,875, which has a stacked structure capable of color separation according to the difference of depth, taking advantage of wavelength dependence of the absorption coefficient of silicon, and a sensor disclosed in JP-A-2003-332551 which has a stacked structure of organic photoelectric conversion layers. However, color separation by the difference in depth of an Si substrate is insufficient because the color sensitivity spectra of vertically adjacent photoelectric portions overlap with each other. As another solution to the above problems, it is known that an aperture ratio can be increased by a structure having a signal reading substrate and an amorphous silicon photoelectric layer and an organic photoelectric layer formed on the substrate.

There are several known techniques pertinent to photoelectric devices, imaging sensors, and photosensors using an organic photoelectric layer. The problems confronting them are improvement of photoelectric conversion efficiency and reduction of dark current. Introduction of a pn junction and introduction of a bulk heterojunction have been proposed to address the former problem, and introduction of a blocking layer has been proposed for the latter.

While improvements added to the structure of a device as described above produce appreciable effects, the characteristics of materials are greatly contributory on the performance of a device. The material characteristics govern not only photoelectric conversion efficiency (inclusive of exciton dissociation efficiency and charge transport properties) and dark current (inclusive of amount of dark-generated carriers) but also signal responsiveness, the latter of which has seldom been mentioned in reports. A photoelectric device for use as a solid state imaging device is required to satisfy all the requirements of high photoelectric conversion efficiency, low dark current, and fast response. There has been reported no concrete approach to an organic photoelectric material and a device structure that satisfy these requirements.

JP-A-2003-110132 discloses a specific organic pigment for use in a photocurrent multiplication device containing an organic material (semiconductor). However, the device has a low speed in response to “light on” (start of exposure to light) and “light off” (stop of exposure) as low as the order of second or, at the shortest, of millisecond, being far from satisfying the demand for high response speed.

### SUMMARY OF THE INVENTION

An object of the invention is to provide a photoelectric device containing an organic material having a fast response and a solid state imaging device and a photosensor using the photoelectric device.

The present invention provides a photoelectric device having a photoelectric layer containing an organic compound having a partial structure represented by formula (I):

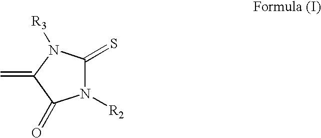

wherein R₂ and R₃ each represent a hydrogen atom, an alkyl group, an alkenyl group, an aryl group, or a heterocyclic group.

In a preferred embodiment of the photoelectric device, the organic compound is represented by formula (II):

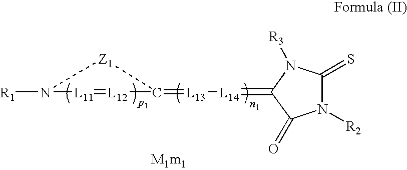

wherein Z₁ represents an atomic group necessary to form a 5- or 6-membered nitrogen-containing heterocyclic ring; R₁, R₂, and R₃ each represent a hydrogen atom, an alkyl group, an alkenyl group, an aryl group, or a heterocyclic group; L₁₁, L₁₂, L₁₃, and L₁₄ each represent a methine group, which may have a substituent and which may be taken together to form a ring; p1 represents 0 or 1; n1 represents an integer of 0 to 4; when n1 is 2 or greater, a plurality of L₁₃s may be the same or different, and a plurality of L₁₄s may be the same or different; M₁ represents anion neutralizing the charge; and m₁ represents a number necessary to neutralize the charge.

In a preferred embodiment of the photoelectric device, the photoelectric layer is formed by vacuum deposition.

The invention also provides a solid state imaging device comprising the photoelectric device of the invention.

The invention also provides a photosensor comprising the photoelectric device of the invention.

The present invention provides a photoelectric device containing an organic material having a fast response and a solid state imaging device and a photosensor using the photoelectric device.

### BRIEF DESCRIPTION OF THE DRAWINGS

FIG. 1 is a schematic cross-section illustrating the structure of the organic photoelectric device according to the invention.

FIG. 2 is a schematic cross-section of a preferred embodiment of the imaging device according to the invention.

FIG. 3 is a schematic cross-section fragmentally showing one pixel of the photoelectric device according to the invention having a BGR layer stacked structure.

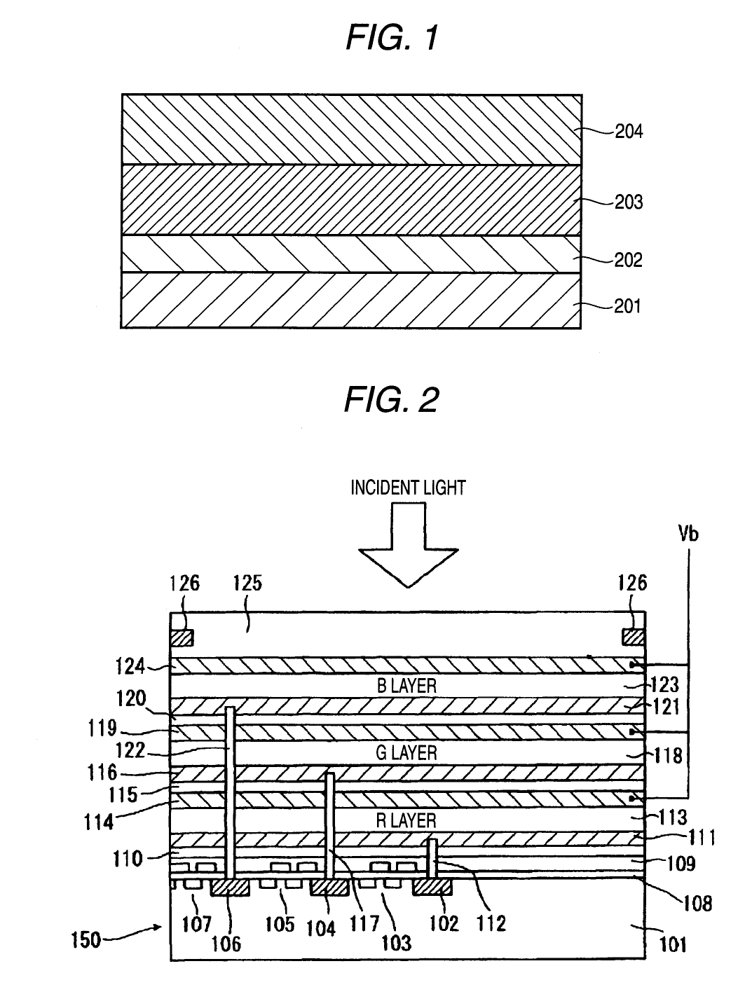

### DESCRIPTION OF REFERENCE NUMERALS

201 Substrate
202 Electrode
203 Photoelectric layer
204 Electrode
1 Antireflection layer
2 IR-cut dielectric multiple layer
3, 4, 5 Protective layers
6 Transparent counter electrode
7 Electron blocking layer
8 P layer
9 N layer
10 Hole blocking layer
11, 12 Layers containing metal wiring
13 Monocrystalline silicon substrate
14 Transparent pixel electrode
15 Plug
16 Pad
17 Light shielding layer
18 Connecting electrode
19 Metal wire
20 Counter electrode pad
21 N layer
22 P layer
23 N layer
24 P layer
25 N layer
26 Transistor
27 Signal reading pad
101 P layer (well)
102, 104, 106 Highly doped region
103, 105, 107 MOS circuit
108 Gate insulating layer
109, 110 Insulating layer
111, 114, 116, 119, 121, 124 Transparent electrode layer
112, 117, 122 Electrode
113, 118, 123 Photoelectric layer
110, 115, 120, 125 Transparent insulating layer
126 Light shielding layer
150 Semiconductor substrate

### DETAILED DESCRIPTION OF THE INVENTION

The present invention is characterized by using an organic compound having a specific partial structure to achieve a fast response in a photoelectric conversion layer (hereinafter “photoelectric layer”), a photoelectric device, an state imaging device, and a photosensor.

The organic compound that can be used in the invention should have at least one partial structure represented by formula (I) (hereinafter simply referred to as a partial structure (I)). The organic compound having the partial structure (I) is not particularly limited but is preferably a merocyanine dye having the partial structure (I), more preferably a dye compound represented by formula (II).

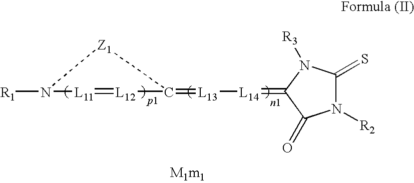

wherein Z₁ represents an atomic group necessary to form a 5- or 6-membered nitrogen-containing heterocyclic ring; R₁, R₂, and R₃ each represent a hydrogen atom, an alkyl group, an alkenyl group, an aryl group, or a heterocyclic group; L₁₁, L₁₂, L₁₃, and L₁₄ each represent a methine group, which may have a substituent and which may be taken together to form a ring; p1 represents 0 or 1; n1 represents an integer of 0 to 4; when n1 is 2 or greater, a plurality of L₁₃s may be the same or different, and a plurality of L₁₄s may be the same or different; M₁ represents an ion neutralizing the charge; and m₁ represents a number necessary to neutralize the charge.

In formula (II), Z₁ represents an atomic group necessary to form a 5- or 6-membered nitrogen-containing heterocyclic ring. Preferred examples of the 5- or 6-membered nitrogen-containing heterocyclic ring formed by Z₁ include oxazole nuclei having 3 to 25 carbon atoms (e.g., 2-3-ethyloxazolyl, 2-3-sulfopropyloxazolyl, 2-3-sulfopropylbenzoxazolyl, 2-3-ethylbenzoxazolyl, 2-3-sulfopropyl-γ-naphthoxazole, 2-3-ethyl-α-naphthoxazole, 2-3-methyl-β-naphthoxazole, 2-3-sulfopropyl-β-naphthoxazole, 2-5-chloro-3-ethyl-α-naphthoxazole, 2-5-chloro-3-ethylbenzoxazolyl, 2-5-chloro-3-sulfopropylbenzoxazolyl, 2-5,6-dichloro-3-sulfopropylbenzoxazolyl, 2-5-bromo-3-sulfopropylbenzoxazolyl, 2-3-ethyl-5-phenylbenzoxazolyl, 2-5-phenyl-3-sulfopropylbenzoxazolyl, 2-5-(4-bromophenyl)-3-sulfobutylbenzoxazolyl, 2-5-(1-pyrrolyl)-3-sulfopropylbenzoxazolyl, 2-5,6-dimethyl-3-sulfopropylbenzoxazolyl, 2-3-ethyl-5-methoxybenzoxazolyl, and 2-3-ethyl-5-sulfobenzoxazolyl); thiazole nuclei having to 25 carbon atoms (e.g., 2-3-ethylthiazolyl, 2-3-sulfopropylthiazolyl, 2-3-ethylbenzothiazolyl, 2-3-sulfopropylbenzothiazolyl, 2-3-methyl-β-naphthothiazolyl, 2-3-sulfopropyl-γ-naphthothiazolyl, 2-3,5-dimethylbenzothiazolyl, 2-5-chloro-3-ethylbenzothiazolyl, 2-5-chloro-3-sulfopropylbenzothiazolyl, 2-3-ethyl-5-iodobenzothiazolyl, 2-5-bromo-3-methylbenzothiazolyl, 2-3-ethyl-5-methoxybenzothiazolyl, and 2-5-phenyl-3-sulfopropylbenzothiazolyl); imidazole nuclei having 3 to 25 carbon atoms (e.g., 2-1,3-diethylimidazolyl, 2-5,6-dichloro-1,3-diethylbenzimidazolyl, 2-5,6-dichloro-3-ethyl-1-sulfopropylbenzimidazolyl, 2-5-chloro-6-cyano-1,3-diethylbenzimidazolyl, and 2-5-chloro-1,3-diethyl-6-trifluoromethylbenzimidazol yl); indolenine nuclei having 10 to 30 carbon atoms (e.g., 3,3-dimethyl-1-pentylindolenine, 3,3-dimethyl-1-sulfopropylindolenine, 5-carboxy-1,3,3-trimethylindolenine, 5-carbamoyl-1,3,3-trimethylindolenine, and 1,3,3-trimethyl-4,5-benzindolenine); quinoline nuclei having 9 to 25 carbon atoms (e.g., 2-1-ethylquinolyl, 2-1-sulfobutylquinolyl, 4-1-pentylquinolyl, 4-1-sulfoethylquinolyl, and 4-1-methyl-7-chloroquinolyl); selenazole nuclei having 3 to 25 carbon atoms (e.g., 2-3-methylbenzoselenazolyl); pyridine nuclei having 5 to 25 carbon atoms (e.g., 2-pyridyl); thiazoline nuclei, oxazoline nuclei, selenazoline nuclei, tetrazoline nuclei, tetrazole nuclei, benzotellurazole nuclei, imidazoline nuclei, imidazo[4,5-quinoxaline]nuclei, oxadiazole nuclei, thiadiazole nuclei, tetrazole nuclei, pyrimidine nuclei, and pyrrolidine nuclei.

The nitrogen-containing heterocyclic ring may be substituted. Preferred examples of the substituent include a halogen atom, an alkyl group (including a cycloalkyl group, a bicycloalkyl group, and a tricycloalkyl group), an alkenyl group (including a cycloalkenyl group and a bicycloalkenyl group), an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an alkoxycarbonyl group, an aryloxycarbonyl group, an amino group (including an anilino group), an ammonio group, an acylamino group, an aminocarbonyl amino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imide group, a phosphino group, a phosphinyl group, a phosphinyloxy group, a phosphinylamino group, a phosphono group, a silyl group, a hydrazino group, an ureido group, a boronic acid group (—B(OH)₂), a phosphate group (—OPO(OH)₂), a sulfate group (—OSO₃H), and other known substituents. The above enumerated group of substituents will hereinafter be referred to as substituents W.

The heterocyclic group recited may be fused to another ring, preferably a benzene ring, a benzofuran ring, a pyridine ring, a pyrrole ring, an indole ring, or a thiophene ring.

More preferred examples of the 5- or 6-membered nitrogen-containing heterocyclic group formed by Z₁ are oxazole nuclei, oxazoline nuclei, benzimidazole nuclei, thiazole nuclei, thiazoline nuclei, indolenine nuclei, and pyrrolidine nuclei. Even more preferred of them are oxazole nuclei, thiazole nuclei, and benzimidazole nuclei. Particularly preferred of them are benzimidazole nuclei, benzothiazole nuclei, and benzoxazole nuclei.

R₁ is a hydrogen atom, an alkyl group (preferably having 1 to 20 carbon atoms, e.g.,methyl, ethyl, n-propyl, isopropyl, n-butyl, n-pentyl, benzyl, 3-sulfopropyl, 4-sulfobutyl, 3-methyl-3-sulfopropyl, 2′-sulfobenzyl, carboxymethyl, or 5-carboxypentyl), an alkenyl group (preferably having 2 to 20 carbon atoms, e.g., vinyl or allyl), an aryl group (preferably having 6 to 20 carbon atoms, e.g., phenyl, 2-chlorophenyl, 4-methoxyphenyl, 3-methylphenyl, or 1-naphthyl), or a heterocyclic group (preferably having 1 to 20 carbon atoms, e.g., pyridyl, thienyl, furyl, thiazolyl, imidazolyl, pyrazolyl, pyrrolidino, piperidino, or morpholino). More preferably R₁ is an alkyl group, particularly an alkyl group having 1 to 6 carbon atoms.

R₂ and R₃ each independently represent a hydrogen atom, an alkyl group (preferably having 1 to 20 carbon atoms, e.g., methyl, ethyl, n-propyl, isopropyl, n-butyl, n-pentyl, benzyl, 3-sulfopropyl, 4-sulfobutyl, 3-methyl-3-sulfopropyl, 2′-sulfobenzyl, carboxymethyl, 5-carboxypentyl, cyanoethyl or ethoxycarbonylmethyl), an alkenyl group (preferably having 2 to 20 carbon atoms, e.g., vinyl or allyl), an aryl group (preferably having to 20 carbon atoms, e.g., phenyl, 2-chlorophenyl, 4-methoxyphenyl, 3-methylphenyl, or 1-naphthyl), or a heterocyclic group (preferably having 1 to 20 carbon atoms, e.g., pyridyl, thienyl, furyl, thiazolyl, imidazolyl, pyrazolyl, pyrrolidino, piperidino, or morpholino). More preferably R₁ is an alkyl group, particularly an alkyl group having 1 to 6 carbon atoms.

L₁₁, L₁₂, L₁₃, and L₁₄ each represent a methine group which may have a substituent. Examples of the substituent are the same as the substituents W recited in connection with Z₁. Preferred of the substituents are an alkyl group, a halogen atom, a nitro group, an alkoxy group, an aryl group, a heterocyclic group, an aryloxy group, an acylamino group, a carbamoyl group, a sulfo group, a hydroxyl group, a carboxyl group, an alkylthio group, and a cyano group, with an alkyl group being more preferred. L₁₁, L₁₂, L₁₃, and L₁₄ each preferably represent an unsubstituted methine group or a methine group substituted with an alkyl group (preferably having 1 to 6 carbon atoms). L₁₁, L₁₂, L₁₃, and L₁₄ each more preferably represent an unsubstituted methine group.

L₁₁, L₁₂, L₁₃, and L₁₄ may be taken together to form a ring. Preferred examples of the ring include a cyclohexene ring, a cyclopentene ring, a benzene ring, and a thiophene ring.

p1 is 0 or 1, preferably 0. n1 is an integer of 0 to 4, preferably 0 to 3, more preferably 1 or 2. When n1 is 2 or greater, a plurality of L₁₃s may be the same or different, and a plurality of L₁₄s may be the same or different.

M₁ represents an ion neutralizing the electric charge, and m₁ is a number necessary to neutralize the charge.

Of the organic compounds having the partial structure (I) preferred is a dye compound represented by formula (III):

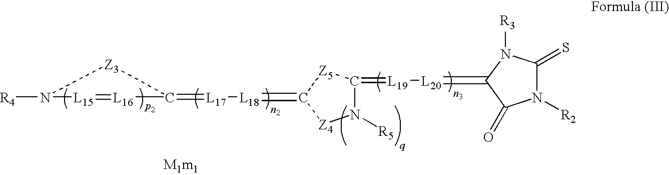

wherein R₂, R₃, M₁, and m₁ are as defined above; Z₃ and R₄ have the same meaning as Z₁ and R₁ in formula (II), respectively; L₁₅, L₁₆, L₁₇, L₁₈, L₁₉, and L₂₀ have the same meaning as L₁₁, L₁₂, L₁₃, and L₁₄ in formula (II); p2 and n2 have the same meaning as p1 and n1 in formula (II), resepctively1; n3 represents 0 or 1; R₅ has the same meaning as R₂ in formula (II); Z₄ and Z₅ each represent an atomic group necessary to form, together with (N—R₅)_{q}, a ring which may be a fused ring and may have a substituent; and q represents 0 or 1.

The ring formed by Z₄, Z₅, and (N—R₅)_{q} is not limited but is preferably a heterocyclic ring, more preferably a 5- or 6-membered heterocyclic ring, even more preferably an acidic nucleus of a general merocyanine dye from which an oxo group or a thioxo group has been removed. In the preferred heterocyclic ring, Z₄ is a thiocarbonyl group (—(C═S)—) including a thioester group and a thiocarbamoyl group; a carbonyl group (—(C═O)—) including an ester group and a carbamoyl group; a sulfonyl group (—(SO₂)—) including a sulfonic ester group and a sulfamoyl group; a sulfinyl group (—(S═O)—); or a cyano group, more preferably a thiocarbonyl group or a carbonyl group. Z₅ represents an atomic group necessary to complete the acidic nucleus.

The term “acidic nucleus” as used herein is defined, e.g., in James (Ed.), The Theory of the Photographic Process, 4th Ed., Macmillan, pp. 197-200 (1977). Specific examples of the acidic nucleus are described in U.S. Pat. Nos. 3,567,719, 3,575,869, 3,804,634, 3,837,862, 4,002,480, and 4,925,777, JP-A-3-167546, and U.S. Pat. Nos. 5,994,051 and 5,747,236.

The acidic nucleus is preferably a heterocyclic group (more preferably 5- or 6-membered) composed of carbon, nitrogen and/or chalcogen (typically oxygen, sulfur, selenium, or tellurium).

Examples of the acidic nucleus include 2-pyrazolin-5-one, pyrazolidine-3,5-dione, imidazolin-5-one, hydantoin, 2- or 4-thiohydantoin, 2-iminooxazolidin-4-one, 2-oxazolin-5-one, 2-thiooxazolidine-2,5-dione, 2-thiooxazoline-2,4-dione, isooxazolin-5-one, 2-thiazolin-4-one, thiazolidin-4-one, thiazolidine-2,4-dione, rhodanine, thiazolidine-2,4-dithione, isorhodanine, indane-1,3-dione, thiophen-3-one, thiophen-3-one 1,1-dioxide, indolin-2-one, indolin-3-one, 2-oxoindazolinium, 3-oxoindazolinium, 5,7-dioxo-6,7-dihydrothiazolo[3,2-a]pyrimidine, cyclohexane-1,3-dione, 3,4-dihydroisoquinolin-4-one, 1,3-dioxane-4,6-dione, barbituric acid, 2-thiobarbituric acid, chroman-2,4-dione, indazolin-2-one, pyrido[1,2-a]pyrimidine-1,3-dione, pyrazolo[1,5-b]quinazolone, pyrazolo[1,5-a]benzimidazole, pyrazolopyridone, 1,2,3,4-tetrahydroquinoline-2,4-dione, 3-oxo-2,3-dihydrobenzo[d]thiophene 1,1-dioxide, and 3-dicyanomethine-2,3-dihydrobenzo[d]thiophene 1,1-dioxide.

The acid nuclei recited above may have another ring fused thereto or may be substituted (with, for example, the substituents W).

Preferred examples of the ring formed by Z₄, Z₅, and (NR₅)_{q} are the above recited acid nuclei from which an oxo group or a thioxo group has been removed. More preferred are hydantoin, 2 or 4-thiohydantoin, 2-oxazolin-5-one, 2-thioxazoline-2,4-dione, thiazolidine-2,4-dione, rhodanine, thiazolidine-2,4-dithione, barbituric acid, and 2-thiobarbituric acid from each of which an oxo group or a thioxo group has been removed. Even more preferred are hydantoin, 2 or 4-thiohydantoin, 2-oxazolidin-5-one, rhodanine, barbituric acid, and 2-thiobarbituric acid from each of which an oxo group or a thioxo group has been removed. Most preferred are 2- or 4-thiohydantoin, 2-oxazolin-5-one, and rhodanine each having an oxo group or a thioxo group removed therefrom.

q is 0 or 1, preferably 1. n3 is 0 or 1, preferably 0. Preference for R₂, R₃, M₁, and m₁ described for formula (II) applies to those of formula (III). Z₃, R₄, L₁₅₋₂₀, p2, and n2 have the same meaning as Z₁, R₁, L₁₁₋₁₄, p1, and n1 of formula (II), respectively, and the same preference for these groups and numbers as described for formula (II) applies to formula (III). R₅ has the same meaning as R₂, and the preference for R₂ applies to R₅.

Specific examples of the compound having the partial structure (I) are shown below.

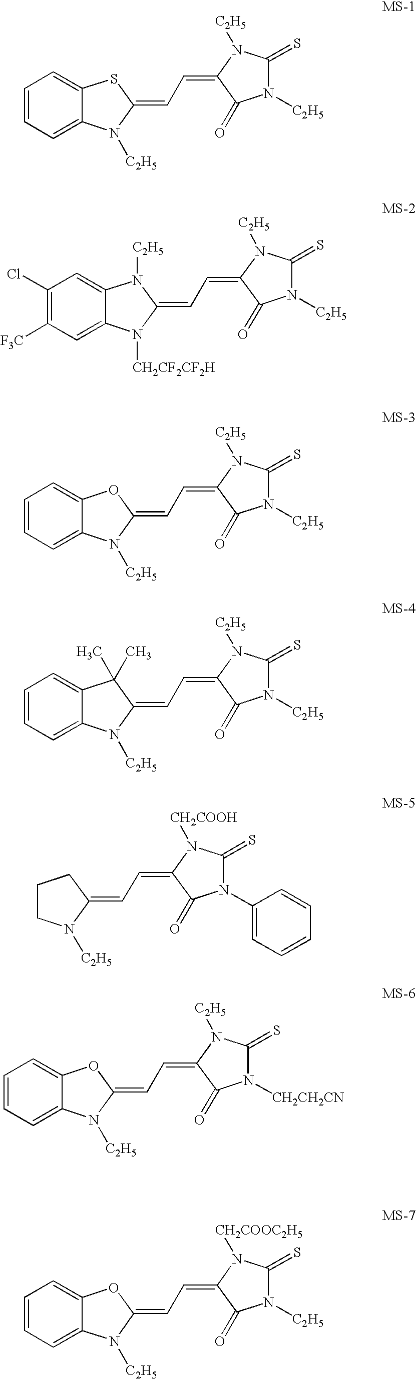

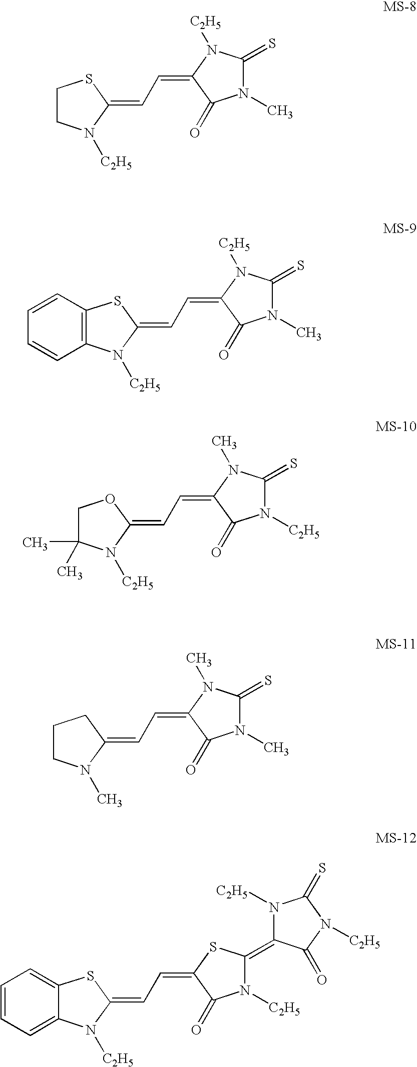

The compounds of the invention are known as, for example, ordinary merocyanine dyes. These dye compounds are synthesized with reference to the literature on methine dyes described infra.

The total thickness of the photoelectric layer or layers in the photoelectric device of the invention is preferably 100 to 500 nm.

### Organic Layer Orientation:

The organic compound that can be used in the organic layer of the photoelectric device is preferably a compound having a conjugated π-electron. It is more desirable that the plane of the pi-electron aligns not perpendicular but more parallel to the substrate (electrode substrate). The angle of the plane to the substrate is preferably 0° to 80°, more preferably 0° to 60°, even more preferably 0° to 40°, still more preferably 0° to 20°, yet more preferably 0° to 10°, and most preferably 0° (namely, parallel to the substrate). The above-described crystalline merocyanine dyes are preferred compounds in this regard.

The photoelectric device of the invention is preferably a stack type color photoelectric device having BGR photoelectric layers that can achieve good full color reproduction, namely a stack of a red photoelectric layer, a green photoelectric layer and a blue photoelectric layer. While all the three photoelectric layers are formed by a proper choice of substances, the compound having the partial structure (I) is preferably used to form a blue photoelectric layer or a green photoelectric layer. The compound having the partial structure (I) is preferably used as an organic p type semiconductor. Organic Layer:

The photoelectric device of the invention has a pair of electrodes and an electromagnetic wave absorption/photoelectric conversion portion between the electrodes. The electromagnetic wave absorption/photoelectric conversion portion is a mixed or stacked organic layer including an electromagnetic wave absorbing site, a photoelectric conversion site, an electron transport site, hole transport site, electron blocking site, a hole blocking site, a crystallization preventing site, an electrode, and an interlaminar contact improving site.

The organic layer preferably contains an organic p type semiconductor (compound) and an organic n type semiconductor (compound). Any p type and n type semiconductor compounds can be used. The semiconductor compounds may or may not have an absorption in the visible and infrared regions. It is preferred to use at least one organic dye compound having an absorption in the visible region. A colorless p type or n type compound may be used in combination with an organic dye compound.

An organic p type semiconductor compound, which is a donor type organic semiconductor, is mostly represented by a hole transport organic compound, i.e., an organic compound ready to donate electrons. To put it another way, when two organic compounds are used in contact with each other, an organic p type semiconductor compound is the one having a lower ionization potential. Any electron donating compound can be used as the p type organic semiconductor compound. Examples of useful p type organic semiconductor compounds include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, aromatic fused carbon ring compounds (e.g., naphthalene derivatives, anthracene derivatives, phenanthrene derivatives, tetracene derivatives, pyrene derivatives, perylene derivatives, and fluoranthene derivatives), and metal complexes having a nitrogen-containing heterocyclic compound as a ligand. As discussed above, an organic compound having a lower ionization potential than an organic compound used in combination as an n-type (acceptor type) compound may also serve as a p type.

The organic n type semiconductor (compound), which is an acceptor type organic semiconductor compound, is mostly represented by an electron transport compound, i.e., an organic compound ready to accept electrons. To put it another way, when two organic compounds are used in contact with each other, an organic n type semiconductor compound is the one having higher electron affinity. Any electron accepting compound can serve as the n type organic semiconductor compound. Examples of useful n type organic semiconductor compounds include aromatic fused carbon ring compounds (e.g., naphthalene derivatives, anthracene derivatives, phenanthrene derivatives, tetracene derivatives, pyrene derivatives, perylene derivatives, and fluoranthene derivatives), 5- to 7-membered heterocyclic compounds having a nitrogen atom, an oxygen atom or a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetraazaindene, oxadiazole, imidazopyridine, pyrralidine, pyrrolopyridine, and thiadiazolopyridine), polyarylene compounds, fluorene compounds, cyclopentadiene compounds, silyl compounds, metal complexes having a nitrogen-containing heterocyclic compound as a ligand. As discussed above, an organic compound having higher electron affinity than an organic compound used in combination as a p type (donor type) compound may also serve as an p type.

While any organic dyes can be used in the organic layer, p type or n type organic dyes are preferred. Examples of useful organic dyes include, but are not limited to, cyanine dyes, styryl dyes, hemicyanine dyes, merocyanine dyes (including zeromethine merocyanine (simple merocyanine)), trinuclear merocyanine dyes, tetranuclear merocyanine dyes, rhodacyanine dyes, complex cyanine dyes, complex merocyanine dyes, allopolar dyes, oxonol dyes, hemioxonol dyes, squarylium dyes, chroconium dyes, azamethine dyes, coumarin dyes, arylidene dyes, anthraquinone dyes, triphenylmethane dyes, azo dyes, azomethine dyes, spiro compounds, metallocene dyes, fluorenone dyes, flugide dyes, perylene dyes, perynone dyes, phenazine dyes, phenothiazine dyes, quinone dyes, diphenylmethane dyes, polyene dyes, acridine dyes, acridinone dyes, diphenylamine dyes, quinacridone dyes, quinophthalone dyes, phenoxazine dyes, phthaloperylene dyes, diketopyrrolopyrrole dyes, dioxane dyes, porphyrin dyes, chlorophyll dyes, phthalocyanine dyes, metal complex dyes, and aromatic fused carbon ring compounds (e.g., naphthalene derivatives, anthracene derivatives, phenanthrene derivatives, tetracene derivatives, pyrene derivatives, perylene derivatives, and fluoranthene derivatives).

For application to a color imaging device contemplated in the present invention, preferred wavelength characteristics tend to result by the use of methine dyes having high freedom of absorption wavelength adjustment such as cyanine dyes, styryl dyes, hemicyanine dyes, merocyanine dyes, trinuclear merocyanine dyes, tetranuclear merocyanine dyes, rhodacyanine dyes, complex cyanine dyes, complex merocyanine dyes, allopolar dyes, oxonol dyes, hemioxonol dyes, squarylium dyes, chroconium dyes, and azomethine dyes.

For the details of these methine dyes, reference can be made to F. M. Harmer, Heterocyclic Compounds—Cyanine Dyes and Related Compounds, John Wiley & Sons, New York, London (1964), and D. M. Sturmer, Heterocyclic Compounds—Special topics in heterocyclic chemistry, John Wiley & Sons, ch. 18, sec. 14, pp. 482-515 (1977), and Rodd's Chemistry of Carbon Compounds, 2nd Ed., vol. IV, part B, ch. 15, pp. 369-422 (1977), Elsevier Science Publishing Co., Inc., New York.

The compounds disclosed in Research Disclosure (hereinafter “RD”) 17643, pp. 23-24. RD 18716, p. 648, right col. to p. 649, right col., RD 308119, p. 996, right col. to p. 998, right col., EP 0565096A1, p. 65, 11. 7-10 are also suitable. Also suitable are the dyes having the structure or the partial structure described in U.S. Pat. No. 5,747,236 (pp. 30-39), U.S. Pat. No. 5,994,051 (pp. 32-43), U.S. Pat. No. 5,340,694 (pp. 21-58, dyes of formulae (XI), (XII), and (XIII) wherein n12, n15, n17, and n18 are each any integer of 0 or greater, preferably 4 or fewer) as well as the specific examples of these dyes shown therein.

The metal complex compound is a metal complex having a ligand containing at least one of nitrogen, oxygen, and sulfur atoms coordinated to a center metal atom thereof. Preferred examples of the center metal ion in the metal complex include, but are not limited to, a beryllium ion, a magnesium ion, an aluminum ion, a gallium ion, a zinc ion, an indium ion, and a tin ion, more preferably a beryllium ion, an aluminum ion, a gallium ion, and a zinc ion. Even more preferred are an aluminum ion and a zinc ion. The metal complex may have various known ligands, including those described in H. Yersin, Photochemistry and Photophysics of Coordination Compounds, Springer-Verlag (1987) and Akio Yamamoto, Yuki Kinzoku Kagaku—Kiso to Ohyo, Shokabo Publishing Co., Ltd. (1982).

The ligand is preferably a nitrogen-containing heterocyclic ligand preferably having 1 to 30 carbon atoms, more preferably 2 to 20 carbon atoms, even more preferably 3 to 15 carbon atoms. The ligand may be monodentate or polydentate, preferably bidentate. Examples of useful ligands include a pyridine ligand, a bipyridyl ligand, a quinolinol ligand, a hydroxyphenylazole ligand (e.g., hydroxyphenylbenzimidazole, hydroxyphenylbenzoxazole or hydroxyphenylimidazole), an alkoxy ligand (preferably having 1 to 30 carbon atoms, more preferably 1 to 20 carbon atoms, even more preferably 1 to 10 carbon atoms, e.g., methoxy, ethoxy, butoxy, or 2-ethylhexyloxy), an aryloxy ligand (preferably having 6 to 30 carbon atoms, more preferably 6 to 20 carbon atoms, even more preferably 6 to 12 carbon atoms, e.g., phenyloxy, 1-naphthyloxy, 2-naphthyloxy, 2,4,6-trimethylphenyloxy, or 4-biphenyloxy), an aromatic heterocyclic oxy ligand (preferably having 1 to 30 carbon atoms, more preferably 1 to 20 carbon atoms, even more preferably 1 to 12 carbon atoms, e.g., pyridyloxy, pyrazyloxy, pyrimidyloxy or quinolyloxy), an alkylthio ligand (preferably having 1 to 30 carbon atoms, more preferably 1 to 20 carbon atoms, even more preferably 1 to 12 carbon atoms, e.g., methylthio or ethylthio), an arylthio ligand (preferably having 6 to 30 carbon atoms, more preferably 6 to 20 carbon atoms, even more preferably 6 to 12 carbon atoms, e.g., phenylthio), a heterocyclic thio ligand (preferably having 1 to 30 carbon atoms, more preferably 1 to 20 carbon atoms, even more preferably 1 to 12 carbon atoms, e.g., pyridylthio, 2-benzimidazolylthio, 2-benzoxazolylthio, or 2-benzothiazolylthio), and a siloxy ligand (preferably having 1 to 30 carbon atoms, more preferably 3 to 25 carbon atoms, even more preferably 6 to 20 carbon atoms, e.g., triphenylsiloxy, triethoxysiloxy or triisopropylsiloxy). Preferred of them are a nitrogen-containing heterocyclic ligand, an aryloxy ligand, an aromatic heterocyclic oxy ligand, and a siloxy ligand. Particularly preferred are a nitrogen-containing heterocyclic ligand, an aryloxy ligand, and a siloxy ligand.

The photoelectric layer which has a p type semiconductor layer and an n type semiconductor layer (preferably a mixed or dispersed semiconductor layer known as a bulk heterojunction structure) in a pair of electrodes preferably contains an orientation-controlled organic compound as at least one of the p type and n type semiconductors.

### Formation of Organic Layer:

The layer containing the organic compound is formed by dry or wet film formation. Dry film formation is effected by, for example, physical vapor deposition (PVD processes such as vacuum evaporation, sputtering, ion plating, and MBE) and chemical vapor deposition (CVD) processes such as plasma-assisted polymerization. Wet film formation processes include casting, spin coating, dipping, and LB method.

When a polymer is used as one or both of the p type and n type semiconductors (compounds), it is easier and therefore preferred to form the organic layer by a wet film formation process. If a polymer is deposited by a dry film formation process such as vacuum evaporation, the polymer can decompose. An oligomer can be used in dry film formation in place of a polymer.

When in using a low molecular compound, a dry film formation technique, particularly vacuum evaporation is preferably used. Vacuum evaporation is basically controlled by parameters including evaporation source heating system (resistance heating evaporation, electron beam evaporation, etc.), shape of evaporant container (crucible, boat, etc.), degree of vacuum, evaporation temperature, substrate temperature, deposition rate, and so forth. It is preferred to rotate the substrate to achieve uniform deposition. A higher degree of vacuum is more preferred. Specifically, the degree of vacuum is preferably 10⁻⁴ Torr or less, more preferably 10⁻⁶ Torr or less, even more preferably 10⁻⁸ Torr or less. All the operations involved in evaporation deposition are preferably conducted in vacuo. Basically, the organic compound must be kept away from direct contact with outer oxygen and moisture. The conditions described above must be controlled strictly because they are influential on the crystalline or amorphous properties, density, denseness, and the like of the organic layer. It is preferred to control the deposition rate by PI or PID control using a film thickness sensor such as a crystal oscillator or an interferometer. In the case of simultaneously depositing two or more compounds, a co-deposition process or a flash deposition process can be used.

### Absorption Wavelength:

As stated previously, the photoelectric device of the invention is preferably a stack type photoelectric device having BGR photoelectric layers that can achieve good full color reproduction, namely a stack of a red photoelectric layer, a green photoelectric layer and a blue photoelectric layer. Each photoelectric layer preferably has the following spectral absorption and/or spectral sensitivity characteristics.

For the sake of convenience, the spectral absorption maximum wavelengths of the photoelectric layers are designated λmax1, λmax2, and λmax 3 in the order of BGR, and the spectral sensitivity maximum wavelengths of the photoelectric layers are designated Smax1, Smax2, and Smax 3 in that order. λmax1 and Smax1 preferably range from 400 to 500 nm, more preferably from 420 to 480 nm, even more preferably from 430 to 470 nm. λmax2 and Smax2 preferably range from 500 nm to 600 nm, more preferably from 520 to 580 nm, even more preferably from 530 to 570 nm. λmax3 and Smax3 preferably range from 600 nm to 700 nm, more preferably from 620 to 680 nm, even more preferably from 630 to 670 nm.

In the case where the photoelectric layer is a stack of three or more sublayers, the distance between the shortest and the longest wavelengths showing a 50% value of the spectral absorption maximum at each of λmax1, λmax2, and λmax3 and a 50% value of the spectral sensitivity maximum at each of Smax1, Smax2, and Smax3 is preferably 120 nm or smaller, more preferably 100 nm or smaller, even more preferably 80 nm or smaller and most desirably 70 nm or smaller. The distance between the shortest and the longest wavelengths showing an 80% value of the spectral absorption maximum at each of λmax1, λmax2, and λmax3 and of the spectral sensitivity maximum at each of Smax1, Smax2, and Smax3 is preferably 20 nm or greater, more preferably 100 nm or smaller, even more preferably 80 nm or smaller, and most desirably 50 nm or smaller. The distance between the shortest and the longest wavelengths showing a 20% value of the spectral absorption maximum at each of λmax1, λmax2, and λmax3 and of the spectral sensitivity maximum at each of Smax1, Smax2, and Smax3 is preferably 180 nm or smaller, more preferably 150 nm or smaller, even more preferably 120 nm or smaller, and most desirably 100 nm or smaller.

Furthermore, in the longer wavelength sides of λmax1, λmax2, λmax3, Smax1, Smax2, and Smax3, the longest wavelength showing a 50% value of the spectral absorption maximum at λmax1, λmax2, and λmax3 and of the spectral sensitivity maximum at Smax1, Smax2, and Smax3 is preferably 460 to 510 nm for λmax1 and Smax1, 560 to 610 nm for λmax2 and Smax2, and 640 to 730 nm for λmax3 and Smax3.

When the compound of the invention has the above described preferred spectral absorption and/or spectral sensitivity characteristics, the imaging device provides a color image with improved color reproduction.

### Thickness of Organic Dye Layer:

When the photoelectric layer is applied to a color imaging device (image sensor), it is preferred that each of the B, G, and R sensitive organic dye layers have a light absorptance of at least 50%, more preferably 70% or more, even more preferably 90% or more (absorbance=1), most preferably 99% or more, in order to improve the photoelectric conversion efficiency and to prevent unnecessary light from passing through into a lower layer thereby to improve color separation. Therefore, a thicker organic dye layer is more favorable for light absorption. Taking the contribution to charge separation into consideration, however, the thickness of the organic dye layer is preferably 30 to 300 nm, more preferably 50 to 250 nm, even more preferably 60 to 200 nm, and most preferably 80 to 130 nm.

### Voltage Application:

To apply voltage to the photoelectric layer increases photoelectric efficiency. The voltage to be applied is not limited, but a necessary voltage depends on the photoelectric layer thickness. In other words, the photoelectric efficiency increases with the electric field applied to the photoelectric layer, but with the applied voltage being equal, the electric field intensity increases as the photoelectric layer thickness decreases. Accordingly, when the photoelectric layer has a small thickness, the voltage to be applied may be relatively low. The electric field to be applied to the photoelectric layer is preferably 1×10⁻² V/cm or more, more preferably 10 V/cm or more, even more preferably 1×10³ V/cm or more, still more preferably 1×10⁴ V/cm or more, yet more preferably 1×10⁵ V/cm or more. While there is no particular upper limit, application of too high an electric field intensity can cause an electric current to flow even in dark. From this viewpoint, the electric field to be applied is preferably 1×10¹⁰ V/cm or less, more preferably 1×10⁷ V/cm or less.

### Other General Requirements:

In the present invention, a stacked structure having at least two photoelectric devices is preferably used. More preferably a stacked structure has three or four, even more preferably three photoelectric devices.

The stacked structure of the photoelectric device of the invention can be used as an imaging device, particularly a solid state imaging device. In a preferred mode of application, the photoelectric layer, photoelectric device, and imaging device of the invention are preferably used with a voltage applied.

The photoelectric device of the invention preferably has a pair of electrodes and a photoelectric layer sandwiched between the electrodes, the photoelectric layer being a stack of at least a p type semiconductor sublayer and an n type semiconductor sublayer. At least one of the p type and n type semiconductor sublayers preferably contains an organic compound. It is more preferred for both the p type and n type semiconductor sublayers contain an organic compound.

### Bulk Heterojunction:

It is preferred that the photoelectric layer (photosensitive layer) between a pair of electrodes in the photoelectric device of the invention have a p type semiconductor sublayer and an n type semiconductor sublayer at least one of which is an organic semiconductor layer and also have an intermediate sublayer having a bulk heterojunction structure between the p type and n type semiconductor sublayers. The bulk heterojunction structure is a mixture of the p type and n type semiconductors. The provision of the bulk heterojunction structure in the photoelectric layer compensates for the short carrier diffusion length of the organic layer, thereby improving the photoelectric conversion efficiency. For the details of the bulk heterojunction structure, reference can be made to JP-A-2005-42356.

### Tandem Structure:

The photoelectric layer (photosensitive layer) of the invention preferably has at least two repeats of pn junction layers (called a tandem structure) composed of alternating p type semiconductor sublayers and n type semiconductor sublayers between a pair of electrodes. A thin conductor layer may be inserted between the repeats of pn junction layers. The conductor is preferably silver or gold, more preferably silver. The number of the repeats of pn junction layers (tandem structure) is not limited. To enhance the photoelectric conversion efficiency, the number of the repeats of pn junction layers is preferably 2 to 100, more preferably from 2 to 50, even more preferably 5 to 40, still more preferably 10 to 30.

While the semiconductors having the tandem structure may be inorganic or inorganic, they are preferably organic materials, particularly organic dyes.

For the details of the tandem structure, reference can be made to JP-A-2005-42356.

### Stack Structure

In a preferred embodiment of the invention, in the case where the photoelectric layer is used with no voltage application, it is preferred that at least two photoelectric layers be stacked one on top of another. While any structure known for a stacked imaging device is applicable to the present invention, a structure having a stack of BGR layers is preferred. A preferred example of such a stack structure is illustrated in FIG. 2.

The solid state imaging device according to the invention has such a photoelectric layer as described in the present embodiment. The solid state imaging device illustrated in FIG. 2 has a stack of photoelectric layers on a scanning circuit. The scanning circuit has an appropriate structure such as a semiconductor substrate having formed thereon an MOS transistor in every unit pixel or a structure having a CCD as an image sensor.

In the case of a solid state imaging device using MOS transistors, for example, incident light having passed through a transparent electrode generates electric charges in the photoelectric layers. On voltage application to the electrodes, the charges are swept in each photoelectric layer to the respective electrodes by the electric field between the electrodes and further moved into the charge storage part of the MOS transistors where they are stored. The charges stored in the charge storage part are transferred to the charge reading part by switching the MOS transistor and then outputted as electrical signals. By this mechanism, full color image signals are inputted in the solid state imaging device having a signal processing part. The structures of the color solid state imaging devices represented by FIG. 2 of JP-A-58-103165 and FIG. 2 of JP-A-58-1013166 are also useful in the invention.

The above described stacked imaging device, preferably three layer stacked imaging device can be fabricated with reference to the method described in JP-A-2002-83946, particularly FIGS. 7 through 23 and paragraphs 0026 through 0038.

### Photoelectric Device:

A preferred embodiment of the photoelectric device according to the invention will be described. The photoelectric device of the present embodiment comprises an electromagnetic wave absorption/photoelectric conversion portion and a charge storage/transfer/reading portion for the electric charges generated by photoelectric conversion.

The electromagnetic wave absorption/photoelectric conversion portion has a stack of at least two layers each capable of absorbing blue light, green light or red light to achieve photoelectric conversion. A blue light absorbing layer (layer B) absorbs at least light of wavelengths of 400 to 500 nm and preferably has an absorptance of 50% or more at the peak wavelength in that region. A green light absorbing layer (layer G) absorbs at least light of wavelengths of 500 to 600 nm and preferably has an absorptance of 50% or more at the peak wavelength in that region. A red light absorbing layer (layer R) absorbs at least light of wavelengths of from 600 to 700 nm and preferably has an absorptance of 50% or more at the peak wavelength in that region. These layers may be stacked in any order. In the case of a three-layer stack, the layers may be stacked in the orders of, from the upper side (light incidence side), BGR, BRG, GBR, GRB, RBG and RGB. The layer G is preferably provided as the uppermost layer. In the case of a two-layer stack, when the upper layer is a layer R, layers B and G are provided flush with each other as a lower layer. When the upper layer is a layer B, layers G and R are provided flush with each other as a lower layer. When the upper layer is a layer G, layers B and R are provided flush with each other as a lower layer. It is preferred that the layer G be provided as the upper layer with the layers B and R flush with each other as the lower layer. In the case where the lower layer is two light absorbing layers flush with each other, it is preferable to form a color separation filter layer on the upper layer or between the upper and lower layers in a mosaic pattern. It is possible in some cases to form a fourth or even more layers as an additional layer(s) or on the same plane as the existing layer(s).

The charge storage/transfer/reading portion is provided beneath the electromagnetic wave absorption/photoelectric conversion portion. It is preferred that the lower layer of the electromagnetic wave absorption/photoelectric conversion portion also serves for the function as the charge storage/transfer/reading portion.

In the present invention the electromagnetic wave absorption/photoelectric conversion portion is composed of an organic layer, an inorganic layer, or a mixture of an organic layer and an inorganic layer. While the layers B, G, and R may be either organic or inorganic, it is preferred that the electromagnetic wave absorption/photoelectric conversion portion be composed of an organic layer and an inorganic layer. In this case, where there is one organic layer, there is/are one/two inorganic layer(s). Where there are two organic layers, there is one inorganic layer. When there are one organic layer and one inorganic layer, the inorganic layer forms an electromagnetic wave absorption/photoelectric conversion portion in which two or more inorganic layers having different color sensitivities are provided flush with each other. More preferably, the upper layer is an organic layer which is a layer G, and the lower layers are inorganic layers which are a layer B and a layer R downward. It is possible in some cases to form a fourth or even more layers as an additional layer (s) or on the same plane as the existing layer(s). Where layers B/G/R are formed of organic layers, a charge storage/transfer/reading portion is provided thereunder. Where an inorganic layer is used as an electromagnetic wave absorption/photoelectric conversion portion, this inorganic layer serves as a charge storage/transfer/reading portion.

A particularly preferred embodiment of the device according to the present invention is a device having at least two electromagnetic wave absorption/photoelectric conversion portions, at least one of which is the photoelectric device (preferably an imaging device) of the invention. It is also preferred that the at least two electromagnetic wave absorption/photoelectric conversion portions have a stack of at least two layers. It is also preferred that the upper layer be a layer that absorbs green light to achieve photoelectric conversion.

It is more preferred that the device has at least three electromagnetic wave absorption/photoelectric conversion portions, at least one of which is the photoelectric device (preferably an imaging device) of the invention. It is also preferred that the upper layer be capable of absorbing green light to achieve photoelectric conversion. It is also preferred that at least two out of the three electromagnetic wave absorption/photoelectric conversion portions be inorganic layers, particularly inorganic layers formed in a silicon substrate.

The electromagnetic wave absorption/photoelectric conversion portions formed of the organic layer of the invention is sandwiched between an upper and a lower electrode, i.e., a pixel electrode and a counter electrode. The lower electrode is preferably a pixel electrode.

The counter electrode collects holes preferably from a hole transport photoelectric layer or a hole transport layer. The counter electrode can be made of a metal, an alloy, a metal oxide, an electrically conductive compound, or a mixture thereof. The pixel electrode collects electrons preferably from an electron transport photoelectric layer or an electron transport layer. The material forming the pixel electrode is selected with considerations to adhesion to an adjacent layer such as an electron transport photoelectric layer or an electron transport layer, electron affinity, ionization potential, stability, and so forth. Examples of useful materials include conductive metal oxides such as tin oxide, zinc oxide, indium oxide, and indium tin oxide (ITO); metals such as gold, silver, chromium, and nickel; mixtures or laminates of the metal and conducting metal oxide recited; inorganic conductive substances such as copper iodide and copper sulfide; organic conductive materials such as polyaniline, polythiophene, and polypyrrole; silicon compounds; and laminates of ITO with the material recited. Conductive metal oxides are preferred of them. ITO and IZO (indium zinc oxide) are especially preferred in view of productivity, high conductivity, transparency, and so on. While varying depending on the material, the electrode thickness is usually in the range of 10 nm to 1 μm, preferably 30 to 500 nm, and more preferably 50 to 300 nm.

The pixel electrode and the counter electrode can be formed by various methods chosen according to the material used. For example, an ITO electrode is formed by electron beam deposition, sputtering, resistance heating deposition, chemical reaction (e.g., a sol-gel method), or coating with an ITO dispersion. An ITO film thus formed may be subjected to a UV-ozone treatment, a plasma treatment, or the like.

In the invention, a transparent electrode is preferably formed under a plasma-free condition so as to minimize influences of a plasma on the substrate thereby to secure good photoelectric characteristics. As used herein, the term “plasma-free” means a state that a plasma does not generate during the film formation of a transparent electrode layer or that a distance from the plasma source to the substrate is at least 2 cm, preferably 10 cm or longer, still preferably 20 cm or longer, so that plasma may have been reduced by the time when it reaches the substrate.

Film deposition systems that involve no plasma generation during transparent electrode film formation are exemplified by electron beam (EB) deposition systems and pulse laser deposition systems. Examples of usable EB deposition systems and pulse laser deposition systems are described in Tomei Dodenmaki no Shintenkai, Yutaka Sawada (supervisor), CMC Publishing Co. (1999), Tomei Dodenmaku no Shintenkai II, Yutaka Sawada (supervisor), CMC Publishing Co. (2002), Tomei Dodenmaku no Gijutsu, Japan Society for the Promotion of Science, Ohmsha, Ltd. (1999), as well as the reference literature cited therein. A method of forming a transparent electrode using an EB deposition system or a pulse laser deposition system will hereinafter be called EB deposition and pulse laser deposition.

A film deposition system in which a distance between a plasma source and a substrate is 2 cm or longer and, therefore, a plasma will have been reduced by the time when it reaches the substrate (hereinafter referred to as a plasma-free film deposition system) is exemplified by a facing target sputtering system and an arc plasma deposition system. Examples of these systems are described in the references cited in the preceding paragraph.

The electrodes of the organic electromagnetic wave absorption/photoelectric conversion portion used in the invention will be described in more detail. The organic photoelectric layer is interposed between a pixel electrode layer and a counter electrode layer and can contain an interelectrode material or the like. The term “pixel electrode layer” as referred to herein refers to an electrode layer provided above a substrate having a charge storage/transfer/reading portion formed thereon and is usually divided into sections each corresponding to a single pixel. By this configuration, charge signals converted from light signals by the photoelectric conversion can be read out for every pixel on the charge storage/transfer/signal reading circuit substrate to construct an image.

The term “counter electrode layer” as used herein denotes an electrode layer facing the pixel electrode with the photoelectric layer therebetween and functioning to emit a charge signal of opposite polarity to that swept into the pixel electrode. Because charge signal sweeping does not need to be done separately among pixels, the counter electrode layer is usually a single electrode common to all the pixel electrodes and is therefore called “a common electrode”.

The photoelectric layer is positioned between the pixel electrode layer and the counter electrode layer. The photoelectric conversion function is performed by the photoelectric layer, the pixel electrode layer, and the counter electrode layer.

When there is only one organic layer on a substrate, the layer structure is exemplified by, but not limited to, a substrate, a pixel electrode layer (which is basically a transparent electrode layer), a photoelectric layer, and a counter electrode layer (transparent electrode layer) stacked in the order described. Where there are two organic layers on a substrate, the layer structure is exemplified by, but not limited to, a substrate, a pixel electrode layer (which is basically a transparent electrode layer), a photoelectric layer, a counter electrode layer (transparent electrode layer), an interlayer insulating layer, a pixel electrode layer (which is basically a transparent electrode layer), another photoelectric layer, and a counter electrode layer (transparent electrode layer) stacked in the order described.

The material forming the transparent electrode layer constituting the photoelectric conversion portion in the invention is preferably chosen from those capable of being deposited by use of a plasma-free film deposition system, an EB deposition system, or a pulse laser deposition system. Examples of such materials include metals, alloys, metal oxides, metal nitrides, metal borides, organic conductive compounds, and mixtures thereof. Specific examples thereof include conductive metal oxides such as tin oxide, zinc oxide, indium oxide, IZO, ITO, and indium tungsten oxide (IWO), metal nitrides such as titanium nitride, metals such as gold, platinum, silver, chromium, nickel, and aluminum, mixtures or laminates of the metal and conductive metal oxide recited above, inorganic conductive substances such as copper iodide and copper sulfide, organic conductive substances such as polyaniline, polythiophene, and polypyrrole, and laminates of ITO with the material recited above. Also useful are materials described in Yutaka Sawada (supervisor), Tomei Dodenmaku no Shintenkai, CMC Publishing Co., Ltd. (1999), Yutaka Sawada (supervisor), Tomei Dodenmaku no Shintenkai II, CMC Publishing Co., Ltd. (2002), and Japan Society for the Promotion of Science (ed.), Tomei Dodenmaku no Gijutsu, Ohmsha, Ltd. (1999). Particularly preferred materials for the transparent electrode layer are ITO, IZO, SnO₂ , ATO (antimony-doped tin oxide), ZnO, AZO (Al-doped zinc oxide), GZO (gallium-doped zinc oxide), TiO₂, and FTO (fluorine-doped tin oxide).

The light transmittance of a transparent electrode layer is preferably 60% or more, still preferably 80% or more, even still preferably 90% or more, yet still preferably 95% or more, at the maximum absorption wavelength of the photoelectric conversion layer for which the transparent electrode layer serves. A preferred range of the surface resistivity of a transparent electrode layer varies depending on whether it is a pixel electrode or a counter electrode and whether the charge storage/transfer/reading portion has a CCD structure or a CMOS structure. In the case of a transparent counter electrode layer, when the charge storage/transfer/reading portion has a CMOS structure, the surface resistivity is preferably not more than 10000 Ω/sq (Ω/□), still preferably 1000 Ω/sq or less. When the charge storage/transfer/reading portion has a CCD structure, the surface resistivity is preferably not more than 1000 Ω/sq, still preferably 100 Ω/sq or less. In the case of a transparent pixel electrode, on the other hand, the surface resistivity is preferably not more than 1,000,000 Ω/sq, still preferably 100,000 Ω/sq or less.

During transparent electrode formation, the substrate temperature is preferably 500° C. or lower, still preferably 300° C. or lower, even still preferably 200° C. or lower, yet still preferably 150° C. or lower. A gas may be introduced during the deposition. Any gas may be employed, such as Ar, He, oxygen, nitrogen, or a mixture thereof. In the case of using an oxide material as a film forming material, it is recommended to use oxygen because an oxygen deficiency can often occur.

### Inorganic Layer:

An inorganic layer as an electromagnetic wave absorption/photoelectric conversion portion will then be described. In the case where the upper layer of the electromagnetic wave absorption/photoelectric conversion portion is an organic layer, the light having passed through the organic layer is converted to a charge signal in the inorganic layer. A pn or a pin junction of crystalline silicon, amorphous silicon, or a semiconductor compound such as GaAs is generally employed as an inorganic layer. A stacked inorganic structure can be formed by the method disclosed in U.S. Pat. No. 5,965,875 can be employed. Specifically, a stacked light sensing portion is formed of silicon, and color is separated in the depth direction of the stacked light sensing portion by making use of wavelength dependence of the absorption coefficient of silicon. Since the color separation is carried out according to the light absorption length (depth) in the silicon layer, the spectra detected in individual stacked light sensing portions are broad. By using the organic layer as the upper layer as described above, i.e., by detecting the light having passed through the organic layer in the depth direction of silicon, the color separation is remarkably improved. When the organic upper layer is a layer G, in particular, light having passed through the organic layer is blue and red light only. As a result, the light is separated into blue light and red light in the depth direction of silicon with improved color separation. When the organic upper layer is a layer B or R, the color separation can be remarkably improved, too, by appropriately selecting the site for electromagnetic wave absorption/photoelectric conversion in the silicon layer in its depth direction. When two organic layers are provided, the function of silicon as the electromagnetic wave absorption/photoelectric conversion portion may be confined fundamentally to one color, and favorable color separation can be accomplished.

A preferred structure of the inorganic layer is a plurality of photodiodes that are stacked within a semiconductor substrate in the depth direction for every pixel. Light is absorbed by the plurality of photodiodes to generate a signal charge in the individual photodiodes, which is read out outside the photodiodes as a color signal. The stack of photodiodes preferably contains at least one of a first photodiode located at the depth where B light is absorbed and a second photodiode located at the depth where R light is absorbed, and each of the photodiodes preferably has a color signal reading circuit for reading a color signal corresponding to the charge signal generating in the individual photodiode. This structure allows for color separation without using a color filter. In some cases, the structure enables detecting a negative sensitivity component of light, which will further improve the color reproducibility. The junction of the first photodiode as referred to above is preferably formed at a depth up to about 0.2 μm from the semiconductor substrate surface, while that of the second photodiode is preferably formed at a depth up to about 2 μm from the semiconductor substrate surface.

The inorganic layer preferably has the structure of a photoconductive light sensor, a light sensor of pn or pin junction type, a Schottky barrier light sensor, an MSM (metal-semiconductor-metal) light sensor, or a phototransistor light sensor. In the present invention it is preferred to use a light sensor comprising a single semiconductor substrate in which first and second electroconductive regions having opposite conductivities alternate in the substrate thickness direction. The junctions between the adjoining first and second conductive regions are positioned at depths suited to carry out photoelectric conversion of light components having different wavelength ranges. The single semiconductor substrate is preferably monocrystalline silicon. Use of a monocrystalline silicon substrate enables color separation taking advantage of the dependence of absorption wavelength characteristics on the depth of a silicon substrate.

Examples of useful inorganic semiconductors include compound semiconductors such as InGaN, InAlN, InAlP, and InGaAlP. InGaN semiconductors are compounds with an In content adjusted so as to have a maximum absorption in the blue wavelength range, being represented by compositional formula: InₓGa₁₋ₓN (0<x<1).

These compound semiconductors are prepared by metalorganic chemical vapor deposition (MOCVD). InAlN compounds, which are nitrides having Al belonging to the group 13 similarly to Ga, are useful as a short wavelength light sensor similarly to InGaN compounds. InAlP and InGaAlP, which lattice-match with a GaAs substrate, are also useful.

The inorganic semiconductor may have a buried structure. As used herein, the term “buried structure” denotes a structure in which both ends of a short wavelength light sensing portion are covered with a semiconductor different from the short wavelength light sensing portion. The semiconductor covering both ends is preferably a semiconductor having a band gap wavelength shorter than or equal to that of the short wavelength light sensing portion.

The organic layer and the inorganic layer may be joined to each other in any form. An insulating layer is preferably formed between the organic layer and the inorganic layer to provide electric insulation therebetween.

The alternating conductivity different regions are arranged in npn or pnpn order from the light incidence side. The pnpn junctions are preferred for the following reason. The surface potential can be increased by forming a p well on the surface so that holes and a dark current generating near the surface may be trapped thereby to reduce the dark current.

Such a stacked photodiode has a four layer structure (quadruple well structure) formed in the depth direction of silicon. The quadruple well structure is composed of a deepest n layer, p layer, n layer, and a shallowest p layer in the p type silicon substrate in the order described, which are diffused in turn from the surface of the p type silicon substrate. The longer the wavelength of light incident upon the silicon substrate, the deeper the light will penetrate into the silicon before it is absorbed. Since the incoming wavelength and attenuation coefficient have a relation unique to silicon, the depths of the pn junctions are designed to absorb the respective light components (R, G, and B) of visible light. Similarly, a three layer stacked photodiode structure (triple well structure) having npn junctions can be obtained by forming an n layer, a p layer, and an n layer in this order. In this case, light signals are collected from the n layers, and the p layer is connected to the ground.

When a predetermined reset voltage is applied to a collecting electrode provided for every region (well), each region is depleted, and the capacity of each junction becomes infinitely small. The capacity generating at the junction can thus be minimized.

### Auxiliary Layer:

The photoelectric device of the invention preferably has a UV absorbing layer and/or an IR absorbing layer as the uppermost layer of the electromagnetic wave absorption/photoelectric conversion portion. The UV absorbing layer absorbs or reflects at least light having a wavelength of 400 nm or shorter. The UV absorbing layer preferably has an absorptance of 50% or higher in a wavelength region of 400 nm or shorter. The IR absorbing layer absorbs or reflects at least light having a wavelength of 700 nm or longer. The IR absorbing layer preferably has an absorptance of 50% or higher in a wavelength region of 700 nm or longer.

The UV absorbing layer and the IR absorbing layer can be formed by known methods. In an example, a mordant layer made of a hydrophilic polymer such as gelatin, casein, glue, or polyvinyl alcohol is provided on the substrate, and a dye having a desired absorption wavelength is added to the mordant layer, or the mordant layer is dyed with the dye, to form a colored layer. In another example, a colored resin is used, which is obtained by dispersing a specific colorant in a transparent resin. For example, a colored resin layer made of a polyamino resin having a colorant dispersed therein may be used, as disclosed by JP-A-58-46325, JP-A-60-78401, JP-A-60-184202, JP-A-60-184203, JP-A-60-184204, and JP-A-60-184205. A coloring material comprising a photosensitive polyimide resin is also usable. The photosensitive aromatic polyimide resin disclosed in JP-B-7-113685, which has a photosensitive group in its molecule and cures at or below 200° C., having dispersed therein a colorant is usable. A colored resin having the pigment disclosed in JP-B-7-69486 is also usable.

In the invention, a dielectric multiple layer is preferably used; for the dielectric multiple layer has sharp wavelength dependence of light transmission.

The individual electromagnetic wave absorption/photoelectric conversion portions are preferably separated by an insulating layer. The insulating layer can be formed of transparent insulating materials such as glass, polyethylene, polyethylene terephthalate, polyether sulfone, and polypropylene. Silicon nitride, silicon oxide, and the like are also useful. In particular, a silicon nitride layer formed by plasma assisted CVD is preferably used because of its denseness and good transparency.

To prevent contact with oxygen, moisture, etc., a protective layer or a sealing layer can be provided. Examples of the protective layer include a diamond thin film, an inorganic material layer made of a metal oxide, a metal nitride, etc., a polymer layer made of a fluororesin, poly(p-xylene), polyethylene, a silicone resin, a polystyrene resin, etc., and a layer made of a photocurable resin. It is also possible to cover a device portion with glass, a gas-impermeable plastic, a metal, etc. and package the device per se with a suitable sealing resin. In this case, a highly moisture absorbing substance may be incorporated inside the package.

A microlens array may be provided on the light sensor to improve light collecting efficiency.

### Charge Storage/Transfer/Reading Portion:

With respect to the charge storage/transfer/reading portion, reference can be made, for example, to JP-A-58-103166, JP-A-58-103165, and JP-A-2003-332551. The charge storage/transfer/reading portion may have an appropriate structure, such as a semiconductor substrate having an MOS transistor formed in every unit pixel or a structure having a CCD as a sensor. In the case of a photoelectric device using MOS transistors, for instance, incident light having passed through a transparent electrode generates electric charges in the photoelectric layer. On voltage application to the electrodes, the charges are swept in the photoelectric layer to the respective electrodes by the electric field between the electrodes, moved to and stored in the charge storage part of the MOS transistors where they are stored. The charges stored in the charge storage part are transferred to the charge reading portion by switching the MOS transistor and then outputted as electrical signals. By this mechanism, a full color image signals are inputted in the solid state imaging device having a signal processing part.

A signal charge can also be read out by injecting a given amount of bias charges into a storage diode (a refresh mode) and then storing a fixed amount of the charges (photoelectric conversion mode). The light sensor per se can be made use of as the storage diode, or a storage diode may be provided separately.

Signal reading can be done using a conventional color read-out circuit. A signal charge or current resulting from photoelectric conversion in the light sensing portion is stored in the light sensing portion or a separately provided capacitor. The thus stored charge is read simultaneously with the selection of pixel position by the signal reading technology of a MOS imaging device using the X-Y address system (a so-called CMOS sensor). Another address selection system available is a system in which every pixel is successively selected by a multiplexer switch and a digital shift register and readout as a signal voltage (or charge) on a common output line. An imaging device adopting a two-dimensionally arrayed X-Y address operation is known as a CMOS sensor. In this imaging device, a switch provided in a pixel connected to an X-Y intersection is connected to a vertical shift register. When the switch is turned on by a voltage from the vertical scanning shift register, signals from pixels provided on the same line are read out onto the output line in the column wise direction. The signals are successively read out from an output end through the switch driven by a horizontal scanning shift register.

To read output signals, a floating diffusion detector or a floating gate detector can be used. S/N can be improved by providing pixels with a signal amplifier circuit or using correlated double sampling.

For signal processing, gamma correction by an ADC circuit, digitalization by an AD converter, luminance signal processing, and color signal processing can be applied. Examples of the color signal processing include white balance processing, color separation processing, and color matrix processing. For use in an NTSC system, the RGB signals are converted into YIQ signals.

The charge transfer/reading portion should have a charge mobility of at least 100 cm²/V·sec. Charge mobility of this level is obtained by making a choice of material from among semiconductors belonging to the groups IV, III-V, or II-VI. Among all, it is preferable to use silicon semiconductors in view of advanced fine processing techniques and low cost. Any of a number of charge transfer/reading systems proposed to date can be adopted. A CMOS-type or CCD-type device system is particularly preferred. In the invention, the CMOS-type system is preferred in terms of high-speed reading, pixel addition, partial reading, and power consumption.

### Connection:

Contact parts connecting the individual electromagnetic wave absorption/photoelectric conversion portions to the charge storage/transfer/reading portion may be made of any metal. It is preferable to use a metal selected from copper, aluminum, silver, gold, chromium, and tungsten, with copper being particularly preferred. A contact part should be provided between individual electromagnetic wave absorption/photoelectric conversion portions and the charge storage/transfer/reading portion. In the case of the stacked structure having blue, green and red light photosensitive units, it is necessary to connect an electrode for collecting electrons from the blue sensitive unit to a corresponding charge transfer/reading portion, to connect an electrode for collecting electrons from a green sensitive unit to a corresponding charge transfer/reading portion, and to connect an electrode for collecting electrons from a red sensitive unit to a corresponding charge transfer/reading portion.

### Fabrication Process:

The stacked photoelectric device according to the present invention can be fabricated in accordance with a so-called micro fabrication process employed in the production of known integrated circuits and the like. The process basically includes repetition of pattern exposure with the use of actinic light rays or electron beams (i- or g-line of mercury, excimer laser beam, X-rays, electron beam, etc.), pattern formation by development and/or burning, provision of device-forming materials (by coating, vapor deposition, sputtering, CVD, etc.), and removal of non-pattern areas (by heating, dissolution, etc.).

### Use:

A chip size of the device is chosen from brownie size (120 size), 135 size, APS size, 1/1.8-inch size, and even smaller sizes. A pixel size of the stacked photoelectric device according to the invention is expressed in terms of a circle-equivalent diameter corresponding to a maximum area of the electromagnetic absorption/photoelectric conversion portion. The pixel size is preferably, but not limited to, 2 to 20 μm, more preferably 2 to 10 μm, and even more preferably 3 to 8 μm. When the pixel size exceeds 20 μm, resolution reduces. With a pixel size smaller than 2 μm, resolution reduces probably due to radio interference between the pixels.

The photoelectric device of the invention is suited for use in digital still cameras. It is preferably used in TV cameras as well. Other applications it can find include digital camcorders, surveillance cameras (for use in, for example, office buildings, parking lots, banking facilities, unmanned loan machines, shopping malls, convenience stores, outlet malls, department stores, pachinko parlors, karaoke boxes, video game arcades, and hospitals), other various sensors (e.g., video door intercoms, authentication sensors, sensors for factory automation, robots for household use, industrial robots, and piping inspection systems), medical sensors (e.g., endoscopes and fundus cameras), teleconference systems, television telephones, camera-equipped mobile phones, automobile safety running systems (e.g., back guide monitors, collision prediction systems, and lane-keeping assist systems), and sensors for video games.

Above all, the photoelectric device of the invention is suitable for use in a television camera. This is because the photoelectric device does not need an optical system for color separation, which allows for size and weight reduction of a television camera. It is especially suited to a television camera for high-definition broadcast because of its high sensitivity and resolution. As used herein, the term “television camera for high-definition broadcast” includes a camera for digital high-definition broadcast.

Furthermore, the photoelectric device of the invention eliminates the need of an optical low pass filter, which will bring about further improved sensitivity and resolution.

The fact that the photoelectric device of the invention can be designed to have a reduced thickness and needs no optical system for color separation makes it possible to shoot various scenes with a single camera by changing the photoelectric devices according to the shooting situation. More specifically, mere changing the photoelectric devices makes a single camera able to meet a variety of requirements in shooting various scenes, for example, scenes in which different sensitivities are required, such as “a circumstance with different degrees of brightness such as daytime and nighttime” and “a still subject and a moving subject” and scenes requiring different spectral sensitivities or color reproducibilities. It is no more necessary to carry a plurality of TV cameras, which lessens the burden on a camera operator. The photoelectric devices to be prepared for changing include not only those meeting the above mentioned requirements but one for shooting with infrared light, one for shooting in black and white, and those having different dynamic ranges.

The TV camera according to the invention can be constructed by reference to The Institute of Image Information and Television Engineers (ed.), Television Camera no Sekkei Gijutsu, Corona Publishing Co., Ltd., ch. 2 (1999). For example, replacing the optical system for color separation and the imaging device in the basic configuration of TV camera shown in FIG. 2.1 with the photoelectric device of the invention provides the above described TV camera.

The above described stacked light sensor may be arrayed to provide an imaging device or may be used alone as a light sensor or a color light sensor such as a biosensor or a chemical sensor.

### Preferred Photoelectric Device:

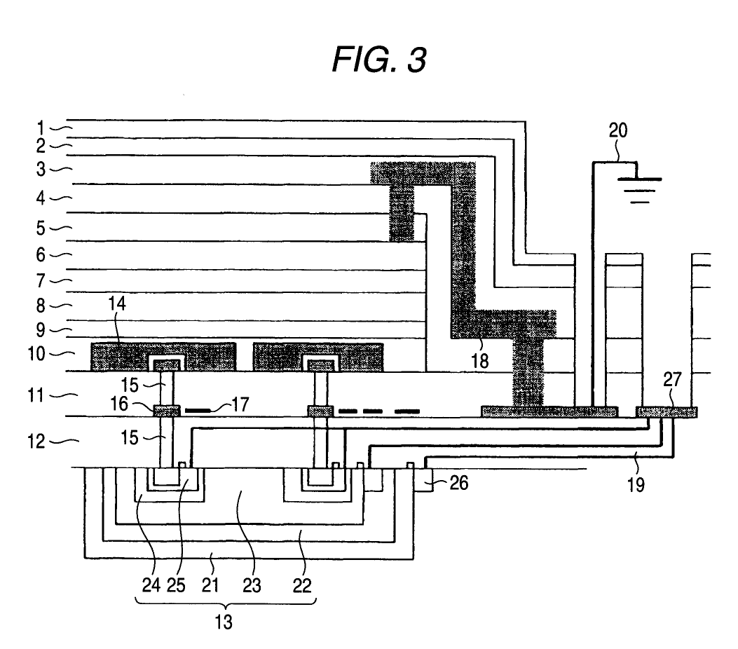

A preferred photoelectric device of the invention will be illustrated by referring to FIG. 3. In FIG. 3, numeral 13 indicates a monocrystalline silicon substrate which also serves as electromagnetic wave absorption/photoelectric conversion portions for B light and R light and a storage/transfer/reading portion for the charge generated by photoelectric conversion. A p-type silicon substrate is usually employed. Numerals 21, 22, and 23 indicate an n layer, a p layer and another n layer, respectively, formed in the silicon substrate 13. The n layer 21 is an R light signal charge storage portion where R light signal charge resulting from photoelectric conversion at the pn junction is stored. The thus stored charge is connected to a signal-reading pad 27 through a metal wire 19 via a transistor 26. The n layer 23 is a Blight signal charge storage portion where B light signal charge resulting from photoelectric conversion at the pn junction is stored. The thus stored charge is connected to the signal reading pad 27 through the metal wire 19 via a transistor similar to the transistor 26. Although the n layers as well as the p layer, transistors, metal wiring, etc. are schematically shown in FIG. 3, the structure and configuration of these elements are appropriately selected as previously discussed. Since the incident light is to be separated into B light and R light according to the depth of the silicon substrate, it is important to properly design the depth of the pn junctions from the surface of the silicon substrate, the dopant concentration, and the like. A layer 12 is made mainly of silicon oxide, silicon nitride, etc. and contains metal wiring. The layer 12 preferably has as small a thickness as possible, e.g., 5 μm or less, preferably 3 μm or less, even more preferably 2 μm or less. A layer 11 is also made mainly of silicon oxide, silicon nitride, etc. Each of the layers 11 and 12 has a plug 15 for sending a signal charge of G light to the silicon substrate. The plugs 15 connect to each other at a pad 16 provided between the layers 11 and 12. The plug is preferably made mainly of tungsten, and the pad 16 is preferably made mainly of aluminum. A barrier layer overlying the metal wiring described above is preferably provided. The signal charge of G light sent via the plugs 15 is stored in an n layer 25 provided in the silicon substrate 13. The n layer 25 is isolated by a p layer 24. The stored charge is connected to the signal reading pad 27 through the metal wire 19 via a transistor similar to the transistor 26. A light shielding layer 17 is provided in the layer 11 to prevent photoelectric conversion from occurring at the pn junction between the p layer 24 and the n layer 25 and causing a noise. The light shielding layer is usually made mainly of tungsten, aluminum, etc. The layer 11 preferably has as small a thickness as possible, preferably of 3 μm or less, more preferably 2 μm or less, even more preferably 1 μm or less. It is preferable that the signal reading pad 27 be provided for each of the B, G and R signals. The above described configuration can be fabricated by a conventional process known as CMOS technology.

The electromagnetic wave absorption/photoelectric conversion portion for G light is shown by numerals 6, 7, 8, 9, 10, and 14. The numerals 6 and 14 are transparent electrodes, i.e., pixel electrodes 14 and a common counter electrode 6. While the pixel electrode 14 itself is transparent, it is often needed to provide a part made of aluminum, molybdenum, etc. at the connection to the plug 15 to secure an electrical connection. A bias voltage is applied between these pairs of transparent electrodes via the wiring from a connecting electrode and a counter electrode pad 20. In a preferred structure, a positive bias voltage is applied to the pixel electrodes 14 relative to the counter electrode 6 to help electrons be stored in the n layer 25. In this case, a layer 7 is an electron blocking layer, a layer 8 is a p layer, a layer 9 is an n layer, and a layer 10 serves as a hole blocking layer. This is a typical organic layer structure. The total thickness of the organic layers 7, 8, 9 and 10 is preferably 0.5 μm or less, more preferably 0.4 μm or less, and even more preferably 0.3 μm or less. The thicknesses of the transparent counter electrode 6 and the transparent pixel electrodes 14 are preferably 0.2 μm or less. Layers 3, 4, and 5 are protective layers made mainly of silicon nitride, etc. The protective layers 3, 4, and 5 allow for easily forming the layers including the organic layers. In particular, the protective layers reduce damages to the organic layers that can occur during resist pattern formation and etching in the formation of the connecting electrodes 18. In order to avoid the steps of forming a resist pattern and etching, the connecting electrodes may be formed using a mask. The protective layers 3, 4, and 5 each preferably have a thickness of 0.5 μm or less as long as the above described performance requirements are satisfied. The protective layer 3 protects the connecting electrodes 18. A layer 2 is an IR-cut dielectric multiple layer. A layer 1 is an antireflection layer. A total thickness of the layers 1, 2, and 3 is preferably not more than 1 μm.

While the photoelectric device discussed above by way of FIG. 3 includes four G pixels per B pixel and per R pixel, the photoelectric device may have one G pixel for every B pixel and every R pixel, three G pixels per B pixel and per R pixel, or two G pixels per B pixel and per R pixel. The photoelectric device may have any other constitution of color pixels. While the present invention has been described with particular reference to its preferred embodiments, the invention is not construed as being limited to the preferred embodiments.

### Examples

The present invention will now be illustrated in greater detail with reference to Examples, but it should be understood that the invention is not limited thereto.

### Example 1

A cleaned ITO substrate was set in a vapor evaporation system, and an organic compound, MS-1, was deposited thereon to a thickness of 200 nm. A patterned mask having an effective area of 2 mm by 2 mm was placed on the organic thin layer, and aluminum was deposited thereon to a thickness of 100 nm to provide a photoelectric device (designated device 1).

### Example 2

A photoelectric device designated device 2 was fabricated in the same manner as in Example 1, except for replacing MS-1 with MS-2.

### Comparative Example 1

A comparative photoelectric device designated device 3 was made in the same manner as in Example 1, except for replacing MS-1 with a comparative compound below.

### Comparative Compound:

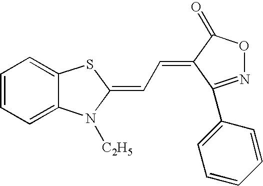

Each of the devices was evaluated by applying a bias of 10 V between the ITO side as a negative electrode and the aluminum electrode as a positive electrode and measuring the time needed for the photocurrent to reach 95% of the saturation. The results obtained are shown in Table 1 below.

TABLE 1

| Device | | Response Time (95% of saturated | |
|---|---|---|---|
| No. | Organic Dye | photocurrent) | |
| 1 | MS-1 | <100 | μs |
| 2 | MS-2 | 300 | μs |
| 3 | Comp. | 30 | ms |
| | compound | | |

It is seen that the devices 1 and 2 according to the invention respond two or more orders of magnitude faster than the comparative device 3.

### Example 3

The device of Example 1 was used as the G layer in the stacked structure of FIG. 2 to provide a color imaging device exhibiting excellent color separation.

The device of Example 1 or 2 was used as the layers 8 and 9 of the photoelectric conversion portion in FIG. 3 to provide a color imaging device exhibiting excellent color separation.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. A photoelectric device comprising a photoelectric conversion layer comprising an organic compound having a partial structure represented by the following formula (I): 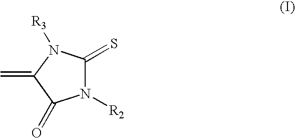
wherein R₂ and R₃ each independently represent a hydrogen atom, an alkyl group, an alkenyl group, an aryl group, or a heterocyclic group.

2. The photoelectric device according to claim 1, wherein the organic compound is represented by the following formula (II): 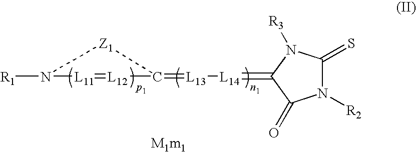
wherein Z₁ represents an atomic group necessary to form a 5- or 6-membered nitrogen-containing heterocyclic ring; R₁, R₂, and R₃ each independently represent a hydrogen atom, an alkyl group, an alkenyl group, an aryl group, or a heterocyclic group; L₁₁, L₁₂, L₁₃, and L₁₄ each independently represent a methine group, which may have a substituent and which may be taken together to form a ring; p1 represents 0 or 1; n1 represents an integer of from 0 to 4; when n1 is 2 or greater, a plurality of L₁₃s may be the same or different, and a plurality of L₁₄s may be the same or different; M₁ represents an ion neutralizing the charge; and m₁ represents a number necessary to neutralize the charge.

3. The photoelectric device according to claim 1, wherein the organic compound is represented by the following formula (III): 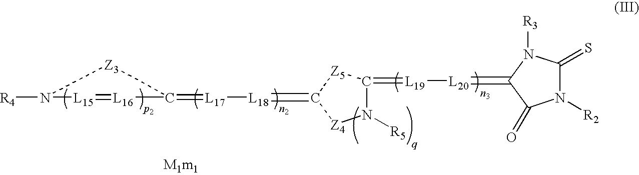
wherein Z₃ represents an atomic group necessary to form a 5- or 6-membered nitrogen-containing heterocyclic ring; R₂, R₃, R₄, and R₅ each independently represent a hydrogen atom, an alkyl group, an alkenyl group, an aryl group, or a heterocyclic group; L₁₅, L₁₆, L₁₇, L₁₈, L₁₉, and L₂₀ each independently represent a methine group, which may have a substituent and which may be taken together to form a ring; p2 represents 0 or 1; n2 represents an integer of from 0 to 4; when n2 is 2 or greater, a plurality of L₁₇s may be the same or different, and a plurality of L₁₈s may be the same or different; n3 represents 0 or 1; Z₄ and Z₅ each represent an atomic group necessary to form, together with (N—R₅)_{q}, a ring which may be a fused ring and may have a substituent; q represents 0 or 1; M₁ represents an ion neutralizing the charge; and m₁ represents a number necessary to neutralize the charge.

4. The photoelectric device according to claim 1, wherein the photoelectric layer is formed by vacuum deposition.

5. The photoelectric device according to claim 2, wherein the photoelectric layer is formed by vacuum deposition.

6. The photoelectric device according to claim 3, wherein the photoelectric layer is formed by vacuum deposition.

7. An imaging device comprising the photoelectric device of claim 1.

8. A photosensor comprising the photoelectric device of claim 1.
